(19) United States
(12) Patent Application Publication
(10) Pub. No.: US 2007/0114989 A1
(43) Pub. Date: May 24, 2007

(54) Apparatus and Methods for Magnetic Through-Skin Sensing

(75) Inventor: Paul R. Arntson, Bothell, WA (US)

Correspondence Address: LEE & HAYES, PLLC, 421 W. RIVERSIDE AVE., SUITE 500, SPOKANE, WA, 99201, US

(73) Assignee: THE BOEING COMPANY, Chicago, IL (US)

(21) Appl. No.: 11/624,587

(22) Filed: Jan. 18, 2007

Related U.S. Application Data
(63) Continuation-in-part of application No. 10/656,595, filed on Sep. 5, 2003, now abandoned.

(51) Int. Cl. G01B 7/14; G01R 33/02; G01B 7/30

(52) U.S. Cl. 324/207.13

(57) ABSTRACT

Apparatus and methods for magnetic through-skin sensing are disclosed. In one embodiment, a sensing system includes a first portion including a magnet having, and a second portion including a magnetic field sensor. The magnet has a magnetic field emanating therefrom. A field-directing member provides a zone of approximately spherically-shaped magnetic force gradient lines, the zone having an angular extent of at least approximately three degrees and the zone extending through the workpiece. The magnetic field sensor is moveable through at least a portion of the zone. The magnetic field sensor senses a characteristic of the shaped magnetic field portion indicative of the desired position for the manufacturing operation.

### CROSS REFERENCE TO RELATED APPLICATIONS

This patent application is a continuation-in-part application of co-pending, commonly-owned U.S. patent application Ser. No. 10/656,595 entitled “Apparatus and Methods for Magnetic Through-Skin Sensing” filed on Sep. 5, 2003, which application is incorporated herein by reference.

### FIELD OF THE INVENTION

The field of the present disclosure relates to apparatus and methods for magnetic through-skin sensing, and more specifically, to manufacturing operations employing magnetic sensing for position location on a workpiece.

### BACKGROUND OF THE INVENTION

Manufacturing operations in many fields typically require accurate positioning of manufacturing tools over a workpiece. One example is the drilling of fastener holes in the field of aircraft manufacturing. Installing fastener holes in airplane parts, particularly the panels or “skins” of an aircraft, commonly requires either “blind” drilling from an external location, or “back” drilling from within the aircraft fuselage. In either case, it may be difficult to drill in the correct location. The difficulty may be caused by the fact that the best drilling in numerous situations is done from the outside in, but the best location information about where to drill is determined by conditions on the inside (i.e. non-drilling) side of the part.

One conventional approach to this problem is to drill a reduced diameter pilot hole from the inside out, and then complete the hole from the outside in, guided by the pilot hole. Another compromise approach is to transfer the location from the inside to the outside using a mechanical guide or measurement device.

Although desirable results have been achieved using the prior art drilling systems and methods, there is still room for improvement. The above-referenced prior art methods may be time and labor intensive, thereby reducing the efficiency of the manufacturing operations. Therefore, a need exists for improved positioning systems and methods for performing manufacturing operations on a workpiece.

### SUMMARY

The present invention is directed to apparatus and methods for magnetic through-skin sensing, and more specifically, to manufacturing operations employing magnetic sensing for position location on a workpiece. Apparatus and methods in accordance with the present invention may advantageously improve the efficiency, throughput, and accuracy of manufacturing operations on a workpiece.

In one embodiment, a sensing system includes a first portion including a magnet having, and a second portion including a magnetic field sensor. The magnet has a magnetic field emanating therefrom. A field-directing member provides a zone of approximately spherically-shaped magnetic force gradient lines, the zone having an angular extent of at least approximately three degrees and the zone extending through the workpiece. The magnetic field sensor is moveable through at least a portion of the zone. The magnetic field sensor senses a characteristic of the shaped magnetic field portion indicative of the desired position for the manufacturing operation.

### BRIEF DESCRIPTION OF THE DRAWINGS

Embodiments of the present invention are described in detail below with reference to the following drawings.

FIG. 1 is a side elevational view of a sensing system in accordance with an embodiment of the invention;

FIG. 2 is a side elevational view of a sensing system in accordance with an alternate embodiment of the invention;

FIG. 3 is a side elevational view of a sensing system in accordance with another alternate embodiment of the invention;

FIG. 4 is an isometric view of a representative manufacturing assembly in accordance with yet another embodiment of the invention;

FIG. 5 is a flowchart of a method of manufacturing incorporating a method of sensing in accordance with a further embodiment of the invention; and

FIG. 6 shows a representative magnetic field for an apparatus in accordance with an embodiment of the invention.

### DETAILED DESCRIPTION

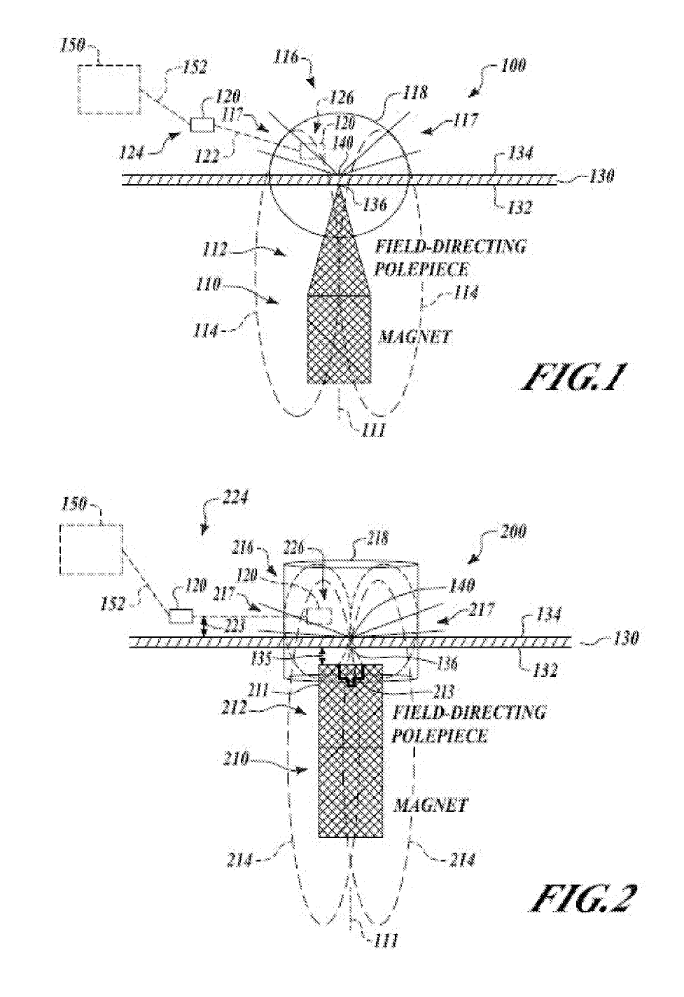

The present invention relates to apparatus and methods for magnetic through-skin sensing, and more specifically, to manufacturing operations employing magnetic sensing for position location on a workpiece. Many specific details of certain embodiments of the invention are set forth in the following description and in FIGS. 1-6 to provide a thorough understanding of such embodiments. One skilled in the art, however, will understand that the present invention may have additional embodiments, or that the present invention may be practiced without several of the details described in the following description.

FIG. 1 is a side elevational view of a sensing system 100 in accordance with an embodiment of the present invention. In this embodiment, the sensing system 100 includes a magnet 110 having a field-directing polepiece 112. A plurality of magnetic field lines (lines of constant strength magnetic force) emanate from the magnet 110. The magnetic field lines exhibit areas (or lines) of approximately constant magnetic force gradient, designated in FIG. 1 as magnetic force gradient lines 114. The field-directing polepiece 112 is suitably shaped so that at least some of the magnetic force gradient lines 114 proximate the field-directing polepiece 112 form a shaped magnetic field portion 116. The shape and permeability of the field-directing polepiece 112 may be adjusted to control the shape of the magnetic force gradient lines 114, and may be determined using, for example, analytical simulations, experimentation, or other suitable techniques.

In one particular embodiment, for example, the field-directing polepiece 112 may be an approximately conical shape, and the zone (or area or region) 117 wherein the magnetic force gradient lines 114 are of approximately spherical (including partially spherical) shape is configured as shown in FIG. 1. For purposes of comparison, an ideally-spherical shape 118 is superimposed on the shaped magnetic field portion 116 of FIG. 1, which demonstrates a relative extent of the zone of approximately spherical shape 117 relative to the ideally-spherical shape 118. In the embodiment shown in FIG. 1, the zone 117 extends from a first boundary of approximately 15 degrees from horizontal to a second boundary of approximately 45 degrees from horizontal.

Controllably varying the shape and permeability of the polepiece 112 enables the size of the approximately spherically-shaped zone 117 to be controlled. In some embodiments, the shape and permeability of the polepiece 112 may be adjusted to maximize the size of the zone 117 in which the magnetic force gradient lines 114 are approximately spherically shaped. In other embodiments, the zone 117 may be adjusted to any other desired sizes.

While it may be appreciated that, in general, magnetic force gradient lines normally emanating from a pole magnet (other than a point magnetic source) that are not shaped using a field-directing polepiece may be approximately elliptically shaped, and may thus be considered to have an approximately spherical shape within a relatively small, relatively localized region having a relatively small angular extent (e.g. approximately two degrees or less), the zone 117 has an appreciably greater angular extent than such relatively localized regions produced by such non-shaped magnetic fields. In contrast, various embodiments of the present invention may be configured to operate with a zone 117 of approximately spherically shaped magnetic force gradient lines having an angular extent (or subtended angle) of approximate three degrees or greater. In other particular embodiments, the zone 117 created using the field-directing polepiece 112 may have an angular extent of approximately 5 degrees or greater, and in further embodiments, a zone having an angular extent of approximately 10 degrees or greater may be employed.

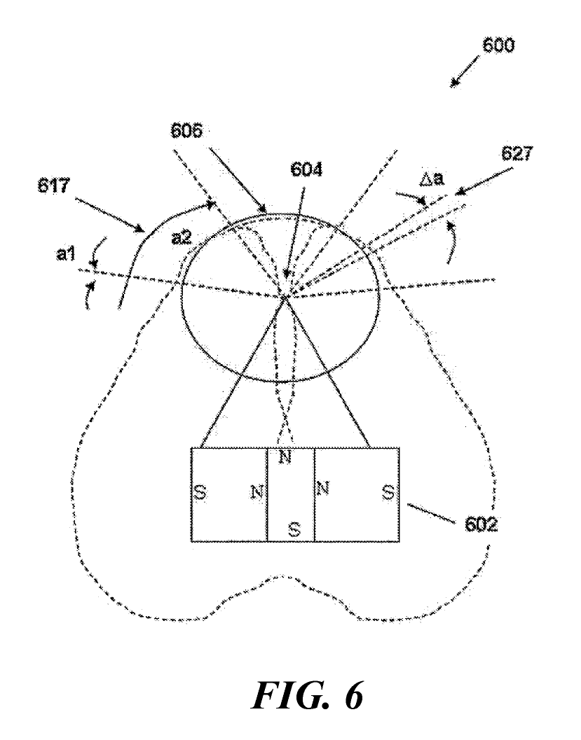

For example, FIG. 6 shows a representative magnetic field 600 for a particular configuration of a magnet 602 and a polepiece 604 in accordance with another embodiment of the invention. In this embodiment, the polepiece 604 is sized and positioned with respect to the magnet 602 to provide a zone 617 in which the magnetic force gradient lines 606 are approximately spherically shaped. More specifically, in this embodiment, the zone 617 extends from a first angle α₁ of approximately 5 degrees to a second angle α₂ of approximately 55 degrees (i.e. a subtended angle of approximately 50 degrees). In an alternate embodiment, the properties of the polepiece 604 may be adjusted to provide a region 627 of approximately spherically shaped magnetic force gradient lines having an angular extent (or subtended angle) Δα of at least approximately three degrees (or greater).

In the embodiment shown in FIG. 6, the polepiece 604 has an approximately conical shape with a height of approximately 0.75 inches, a base diameter of approximately 0.5 inches, and a magnetic relative permeability of approximately 50,000. In addition, in the configuration shown in FIG. 6, the magnetic permeability of the polepiece 604 was assumed to be constant throughout the polepiece 604. Of course, in alternate embodiments, any suitable polepiece shapes, permeability values, and permeability distributions may be used to achieve the desired characteristics of the magnetic force gradient lines 606.

Furthermore, it will be appreciated that various manufacturing environments may require varying degrees of precision, with some manufacturing environments requiring a relatively higher degree of accuracy, and others requiring less accuracy. In general, the accuracy of various embodiments may be adjustably controlled by controlling the shape and permeability properties of the polepiece 604 to adjust the approximate sphericity of the magnetic force gradient lines 606, and thus, the ability of the system to locate an imaginary centerpoint of the zone 617 of approximately spherical magnetic force gradient lines 606. For example, in some manufacturing environments, such as those involving automated drilling operations on contoured or non-contoured surfaces, the magnetic force gradient lines 606 may be controlled to an approximately spherical shape such that a position of an imaginary centerpoint of the approximately spherical zone 617 may be determined to a desired tolerance of approximately +/−0.001 inches, as described more fully below. Of course, in alternate embodiments, the tolerances associated with the location of the centerpoint may be relaxed (e.g. 0.01 inches, 0.1 inches, etc.) or tightened (e.g. 0.0005 inches, 0.0001 inches, etc.) depending on the requirements of the particular application.

Referring again to FIG. 1, the sensing system 100 also includes a magnetic field sensor 120. The magnetic field sensor 120 may be a conventional magnetic field sensor, including, for example, those sensors commercially-available as model PK 88782 industrial sensor from Honeywell International, Inc. of Morristown, N.J., model MLX90215 from Melexis Microelectronic Systems, Inc. of Concord, N.H., the 1321 series sensors from Allegro Microsystems, Inc. of Worcester, Mass., or any other suitable magnetic field sensor. In a particular embodiment, for example, the magnetic field sensor 120 may be a linear Hall effect sensor.

In operation, the magnet 110 may be operatively positioned relative to a workpiece 130. More specifically, the field-directing polepiece 112 of the magnet 110 may be positioned proximate a first surface 132 of the workpiece 130 so that at least a portion of the zone of approximately spherical shape 117 extends through the workpiece 130, and further extends outwardly beyond a second surface 134 of the workpiece 130. In a particular embodiment, the field-directing polepiece 112 may be engaged against (i.e. in contact with) the first surface 132 at a first location 136. Alternately, the field-directing polepiece 112 may be spaced apart from the first surface 132 at the first location 136.

With continued reference to FIG. 1, with the field-directing polepiece 112 operatively positioned relative to the desired first location 136, the magnetic field sensor 120 may be moved along one or more traversing paths 122 that pass at least partially through the shaped magnetic field portion 116. In the embodiment shown in FIG. 1, the traversing path 122 extends at least partially through the zone of approximately spherical shape 117. As the magnetic field sensor 120 is moved from a first sensor position 124 outside of the zone of approximately spherical shape 117 to a second sensor position 126 (depicted in phantom lines) within the zone of approximately spherical shape 117 (or vice versa from the second sensor position 126 to the first sensor position 124), the magnetic field sensor 120 senses the magnetic field lines 114 within the zone of approximately spherical shape 117.

From the known shape of the zone of approximately spherical shape 117, and the magnetic field strength values determined by the magnetic field sensor 120 along the traversing path 122, a second location 140 on the second surface 134 of the workpiece 130 may be determined. In an exemplary embodiment, the second location 140 is directly opposite from the first location 136, and the second location 140 represents a location on the second surface 134 of the workpiece 130 at which a manufacturing operation (e.g. drilling) is desired to be performed. Alternately, the second location 140 may be offset (e.g. by a predefined offset distance along the second surface 134) from a desired location at which a manufacturing operation is to be performed.

The magnetic sensor 120 may transmit one or more sensing signals to a data system 150 via a communication link 152 (e.g. an electrically conductive lead or a wireless link). The data system 150 may, in turn, process the sensing signals to determine the second location 140, or may take other action in response to the sensing signals, including, for example, transmitting one or more control signals to operatively position a manufacturing tool for performing manufacturing operations of the workpiece 130 at a desired location, as described more fully below.

In one particular aspect of the embodiment shown in FIG. 1, the shaped magnetic field portion 116 may be suitably shaped so that the second location 140 is at an approximate center of the zone of approximately spherical shape 117. Thus, the second location 140 (i.e. the center of the zone of approximately spherical shape 117) may be suitably indexed to a desired location on the second surface 134 (e.g. to mark a desired drilling location) by proper positioning of the magnet 110 relative to the first surface 132. Furthermore, since the magnetic force gradient lines 114 of the shaped magnetic field portion 116 approximate a zone of approximately spherical shape 117 in the vicinity of the second surface 134 where the magnetic field sensor 120 is traversed, the sensing system 100 may advantageously be relatively insensitive to the normality of a longitudinal axis 111 of the magnet 110 relative to the workpiece 130, as well as the approach angle of the magnetic field sensor 120 along the traversing path 122 relative to the second surface 136. In one particular embodiment, for example, where the shape of the entirety shaped magnetic field portion 116 is perfectly spherical, the sensing system 100 may be extremely insensitive to such normality and approach angle conditions. Typically, in the embodiment shown in FIG. 1, the degree of non-normality tolerated by the sensing system 100 may be a function of the accuracy with which a sphere is approximated by the zone of approximately spherical shape 117 of the shaped magnetic field portion 116.

Embodiments of sensing systems in accordance with the present invention may be used, for example, in applications where location information needs to be transferred through an opaque surface. For example, in one exemplary application, a sensing system may be employed in a process of joining an aircraft skin to structural components wherein the fastener locations may be determined from the inside of the structure via predrilled pilot holes, and the location of those pilot holes needs to be determined from the outside of the applied skin. In such an application, the magnet and the field-directing polepiece would typically be located on the interior side of the aircraft skin adjacent the pilot hole, and the magnetic field sensor would be traversed along the outside of the aircraft skin, where there is no visible means of locating the pilot hole.

Alternately, in further embodiments, sensing apparatus and methods in accordance with the present invention may be used in any number of different drilling applications where a location is known on a back side of a workpiece and the information needs to be transferred to a front side in order to properly locate the hole. It may also be appreciated that embodiments of sensing apparatus and methods in accordance with the invention are not restricted to drilling applications, but rather, may generally be used for transferring location information through an opaque medium, preferably a non-magnetic medium. Such alternate applications include, but are not limited to, orienting laminate countertop in carpentry, wood veneers in musical instrument making, fabric coverings in modular office furniture, and an unlimited number of other applications requiring transfer of positional information through an opaque material.

The sensing system 100 may provide significant advantages over alternate, prior art systems. For example, because the magnetic field sensor 120 may be swept along any a wide range of desired traversing paths 122 to determine the second location 140, the sensing system 100 may be easier and more efficient to operate in comparison with alternate systems. Also, as noted above, the sensing system 100 may be relatively less sensitive to non-normality conditions in comparison with prior art systems, thereby providing improved accuracy. Overall, the sensing system 100 may advantageously provide a cost-effective and accurate method of indexing a desired location for performing a manufacturing operation on an outer surface of a workpiece from an inner surface of the workpiece.

It will be appreciated that the workpiece 130 may be a substantially planar workpiece as shown in FIG. 1, or alternately, may be any other suitably contoured or non-planar shape. Preferably, the workpiece 130 may be a non-ferromagnetic material so that the shaped magnetic field portion 116 is not distorted, attenuated, or otherwise degraded from its desired shape, strength, or other quantitative or qualitative property. Alternately, if the workpiece 130 includes a ferromagnetic material that may adversely impact the shaped magnetic field portion 116, suitable empirical calibrations or other suitable adjustments may be necessary in order to account for such adverse effects so that the second location 140 may be determined with acceptable accuracy.

Furthermore, it will be appreciated that the ambient magnetic environment surrounding the sensing system 100 should preferably be substantially less than the strength of the shaped magnetic field portion 116. Furthermore, it is desirable that the ferromagnetism of any structure(s) in the vicinity of the sensing system 100 may be negligible, or alternately, approximately homogeneous so as not to appreciably distort the shape of the shaped magnetic field portion 116, especially the zone of approximately spherical shape 117. If, however, instances of repeatable inhomogeneity exist, then the shape of the field-directing polepiece 112 may be appropriately modified to accommodate these instances.

It may be noted that the field-directing polepiece 112 of the magnet 110 is not limited to the particular shape shown in FIG. 1, and may be configured in a wide variety of alternate shapes which may in turn produce other shaped distributions of magnetic flux. For example, in an alternate embodiment, a field-directing polepiece that includes a cylindrical portion with a cone cut-away portion (or frustrum) from the longitudinal axis 111 may produce a more cylindrically-shaped magnetic field portion, and a cylindrical polepiece may produce a more elliptically-shaped magnetic field portion. It may also be appreciated that the shape of the magnetic field portion proximate the field-directing polepiece may be modified in ways other than by the external shape of the field-directing polepiece. For example, in another alternate embodiment, the field-directing polepiece may include an insert portion having a different magnetic permeability than an outer portion of the field-directing polepiece so that a shape of the shaped magnetic field portion may be further modified. In yet another embodiment, successive annular rings of differing magnetic permeability materials (e.g. decreasing permeability for successively smaller rings) may be nested such that the flux density may be forced to inhabit areas preferentially over lower total permeability, thus allowing the overall magnetic flux shape to be varied as desired.

Thus, although the above-described embodiment of the shaped magnetic field portion 116 includes the zone of approximately spherical shape 117 in the vicinity of the second surface 134, a variety of alternate embodiments are possible. In some alternate embodiments, particularly those embodiments having an axially symmetrical magnetic field portion (such as an approximated cylinder or ellipsoid shape), it may be desirable and advantageous to restrict the movement of the magnetic sensor 120 along the traverse path 122 to lie within a particular plane of motion in order to uniquely define a center of the shaped magnetic field portion, thereby providing a more accurate determination of the second location 140 on the workpiece 130.

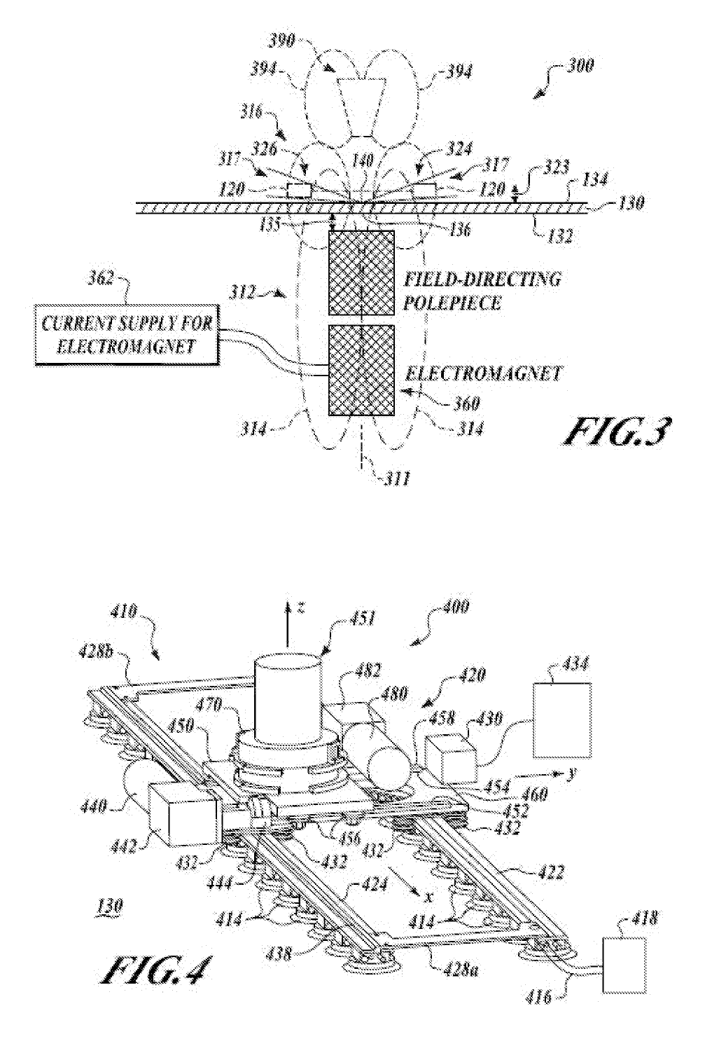

In the following discussion, several alternate embodiments of apparatus and methods are described with reference to FIGS. 2-5. Throughout these discussions, not all of the details of the structural and operational aspects of these additional embodiments will be repeated from the description provided above, but rather, for the sake of brevity, only the more significant aspects and differences of the structural and operational characteristics of such alternate embodiments will be described.

FIG. 2 is a side elevational view of a sensing system 200 in accordance with an alternate embodiment of the invention. In this embodiment, the sensing system 200 includes a magnet 210 that emanates a plurality of magnetic force gradient lines 214, and having a field-directing polepiece 212 that provides a shaped magnetic field portion 216 that includes a zone of approximately cylindrical shape 217. For comparison, an ideally-cylindrical shape 218 is superimposed on the shaped magnetic field portion 216.

As further shown in FIG. 2, in this embodiment, the field-directing polepiece 212 may include an outer portion 211 and an inner portion 213. In one embodiment, the outer portion 211 includes a first material having a first magnetic permeability, and the inner portion 213 includes a second material having a second magnetic permeability. In an alternate embodiment, the inner portion 213 may be a hollow cutout containing air or other suitable substance, or vacuum.

In operation, the magnet 210 is operatively positioned relative to the first surface 132 of the workpiece 130 so that at least a portion of the zone of approximately cylindrical shape 217 extends beyond the second surface 234 of the workpiece 130. In this embodiment, the field-directing polepiece 212 is positioned at a standoff distance 135 from the first location 136 on the workpiece 130. The magnetic field sensor 120 is then moved along a traversing path 222 that passes at least partially through the shaped magnetic field portion 216 from the first sensor position 224 outside the shaped magnetic field portion 216 to the second sensor position 226 within the zone of approximately cylindrical shape 217 (or vice versa). In this embodiment, the traverse path 222 is restricted to lie within a plane that is a constant distance 223 from the second surface 134 of the workpiece 130. As the magnetic field sensor 120 is moved along the traverse path 222, it senses the magnetic force gradient lines 214 and transmits appropriate signals to the data system 150, as described more fully above. From the known shape of the zone of approximately cylindrical shape 217, and the magnetic field strength values determined by the magnetic field sensor 120 along the traversing path 222, the second location 140 on the workpiece 130 may be determined.

FIG. 3 is a side elevational view of a sensing system 300 in accordance with another alternate embodiment of the invention. In this alternate embodiment, the sensing system 300 includes a field-directing polepiece 312 and an electromagnet 360 aligned along a longitudinal axis 311 and emanating a plurality of magnetic force gradient lines 314. A source 362 (e.g. a current supply) is operatively coupled to the electromagnet 360. The field-directing polepiece 312 is positioned at a standoff distance 135 from the first location 136 on the workpiece 130 and provides a shaped magnetic field portion 316 that includes a zone of field sensing 317. In a particular embodiment, for example, the zone of field sensing 317 may be an approximately cylindrically-shaped zone.

In operation, the magnetic field sensor 120 is moved along a traversing path 322 extending from a first sensor position 324 to a second sensor position 326, the first and second sensor positions 324, 326 being disposed within the zone of field sensing 317. The traverse path 322 is restricted to be a constant distance 323 from the second surface 134 of the workpiece 130. As the magnetic field sensor 120 moves along the traverse path 322, it senses the magnetic force gradient lines 314 and transmits appropriate signals to the data system 150, as described more fully above.

Also, because the sensing system 300 includes the electromagnet 360, the overall flux density within the shaped magnetic field portion 316 may be varied (i.e. increased or decreased) by adjustment of the source 362. In one embodiment, for example, the overall flux density may be varied to take advantage of magnetic saturation effects in portions of the core of the electromagnet 360 (or of the field-directing polepiece 312) to further exploit the core's effect on the shaping of the shaped magnetic field portion 316. This may be achievable, for example, by virtue of an effect whereby field fringing may increase as the saturation does not allow the internal density to increase in the area that becomes saturated. Alternately, in further embodiments, the overall flux density may be varied to account for other factors, including but not limited to, attenuations due to varying thicknesses or varying properties of the workpiece 130, inhomogeneities in the ambient magnetic field of the surrounding environment, or any other suitable factors. Based on the known magnetic flux density of the zone of field sensing 317, and the measured data from the magnetic field sensor 120 along the traversing path 322, the second location 140 on the workpiece 130 may be determined.

With continued reference to FIG. 3, in another alternate embodiment, the sensing system 300 may further include a secondary polepiece 390 operatively positioned relative to shaped magnetic field portion 316 and the second surface 134 of the workpiece 130. The secondary polepiece 390 emanates a plurality of secondary magnetic field lines 394 which may be adapted to cause the magnetic force gradient lines 314 of the shaped magnetic field portion 316 to become relatively more concentrated in at least part of the shaped magnetic field portion 316, thus enabling measurements to be made on a weaker field (e.g. using a weaker magnet). In the embodiment having the secondary polepiece 390, compensation may be made to account for distortions and inhomogeneities introduced by the secondary polepiece 390, which may be accomplished, for example, using an iterative approach, an experimental approach, a semi-empirical approach, or any other suitable compensation technique.

It will be appreciated that various embodiments of sensing systems in accordance with the present invention may be utilized in a stand-alone manner, or may be incorporated into a wide variety of existing manufacturing apparatus. Indeed, a virtually limitless number of manufacturing assemblies may be conceived for positioning the field-directing polepiece of the sensing system, and for traversing the magnetic field sensor, in accordance with alternate embodiments of the present invention. Such systems may range from automated, computer controlled manufacturing apparatus, to relatively-simple manually-operated apparatus, and even to simple manual activities performed by an operator. Representative manufacturing assemblies which may be utilized to perform the positioning and traversing operations involved in the operation of the sensing systems in accordance with the present invention include, but are not limited to, those manufacturing assemblies generally described in U.S. Pat. No. 4,850,763 issued to Jack et al., as well as the exemplary manufacturing assemblies disclosed in co-pending, commonly owned U.S. patent application Ser. No. 10/016,524 entitled “Flexible Track Drilling Machine” filed Dec. 10, 2001, co-pending, commonly-owned U.S. patent application Ser. No. 10/606,402 entitled “Apparatus and Methods for Servo-Controlled Manufacturing Operations” filed Jun. 25, 2003, co-pending, commonly-owned U.S. patent application Ser. No. 10/606,443 entitled “Methods and Apparatus for Counter-Balance Assisted Manufacturing Operations” filed Jun. 25, 2003, co-pending, commonly-owned U.S. patent application Ser. No. 10/606,472 entitled “Methods and Apparatus for Manufacturing Operations Using Opposing-Force Support Systems” filed Jun. 25, 2003, and co-pending, commonly-owned U.S. patent application Ser. No. 10/606,473 entitled “Apparatus and Methods for Manufacturing Operations Using Non-Contact Position Sensing” filed Jun. 25, 2003, which patents and patent applications are hereby incorporated by reference.

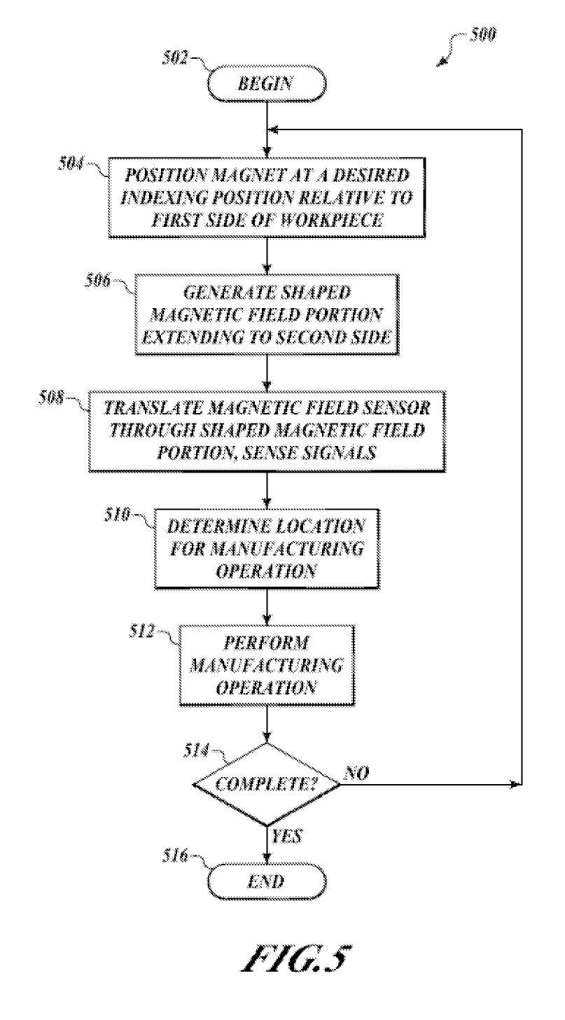

For example, FIG. 4 is an isometric view of a representative manufacturing assembly 400 in accordance with yet another embodiment of the invention. In this embodiment, the manufacturing assembly 400 includes a track assembly 410 controllably attachable to a workpiece 130, and a carriage assembly 420 moveably coupled to the track assembly 410. A sensing component 430 is mounted on the carriage assembly 420 and is operatively coupled to a controller 434. At least one of the sensing component 430 and the controller 434 may also be coupled to a manufacturing tool 451 mounted on the carriage assembly 420. As described more fully below, the sensing component 430 may include at least a portion of a sensing system in accordance with an embodiment of the present invention.

As further shown in FIG. 4, the track assembly 410 may include first and second rails 422, 424, each rail 422, 424 being equipped with a plurality of vacuum cup assemblies 414. The vacuum cup assemblies 414 are fluidly coupled to one or more vacuum lines 416 leading to a vacuum source 418, such as a vacuum pump or the like, such that vacuum may be controllably applied to the vacuum cup assemblies 414 to secure the track assembly 410 to the workpiece 130. The vacuum cup assemblies 414 are of known construction and may be of the type disclosed, for example, in U.S. Pat. No. 6,467,385 B1 issued to Buttrick et al., or U.S. Pat. No. 6,210,084 B1 issued to Banks et al. In alternate embodiments, the vacuum cup assemblies 414 may be replaced with other types of attachment assemblies, including magnetic attachment assemblies, bolts or other threaded attachment members, or any other suitable attachment assemblies.

The rails 422, 424 may be connected by one or more connecting members 428, and may be adapted to bend, twist, and flex to adjust to the contours of the workpiece 130. The carriage assembly 420 may translate along the rails 422, 424 by virtue of rollers 432 that are mounted on an x-axis carriage 460 of the carriage assembly 420 and engaged with the rails 422, 424. In a particular embodiment, each rail 422, 424 may have a V-shaped edge engaged by the rollers 32, and the rollers 32 may include V-shaped grooves that receive the V-shaped edges of the rails 422, 424. In another embodiment, the x-axis carriage 460 may be adapted to flex and twist as needed (i.e. as dictated by the contour of the workpiece 130) as the carriage assembly 420 traverses the rails 422, 422 to allow a limited degree of relative movement to occur between the x-axis carriage 430 and the rollers 432. Consequently, a reference axis of the carriage assembly 420 (in the illustrated embodiment, a z-axis normal to the plane of the x-axis carriage 460) may be maintained substantially normal to the workpiece 130 at any position of the carriage assembly 420 along the rails 422, 424.

As further shown in FIG. 4, a rack 438 for a rack and pinion arrangement is mounted along the rail 424. A first motor 440 and associated first gearbox 442 is mounted on the carriage assembly 420. An output shaft from the first gearbox 442 has a first pinion gear 444 mounted thereon which engages the rack 438 on the rail 424. Thus, rotation of the first pinion gear 444 by the first motor 440 drives the carriage assembly 420 along the rails 422, 424.

With continued reference to FIG. 4, the carriage assembly 420 further includes a y-axis carriage 450 slideably mounted atop the x-axis carriage 460 so that the y-axis carriage 450 can slide back and forth along a y-axis direction perpendicular to the x-axis direction. More particularly, rails 452, 454 are affixed to the opposite edges of the x-axis carriage 460, and rollers 456 are mounted on the y-axis carriage 450 for engaging the rails 452, 454. A rack 458 for a rack and pinion arrangement is affixed to the x-axis carriage 460 along the rail 454. A second motor 480 and associated second gearbox 482 are mounted on the y-axis carriage 450 and drive a second pinion gear (not shown) that engages the rack 458 to drive the y-axis carriage 450 in the y-axis direction.

In operation, the manufacturing assembly 400 may be mounted onto the workpiece 130 and the carriage assembly 420 may be moved to a desired position over the workpiece 130. Specifically, the controller 434 may transmit control signals to the first drive motor 440 to drive the carriage assembly 420 along the track assembly 410, and may also transmit control signals to the second drive motor 480 to adjust the position of the y-axis carriage 4 be coupled to the carriage assembly 420 by, for example, a clamp ring 470 or other suitable structure that provides access to the workpiece 130 for the manufacturing tool 451.

It will be appreciated that the sensing component 430 may include a portion of a sensing system in accordance with an embodiment of the present invention. For example, in alternate aspects, the manufacturing assembly 400 may be mounted on the first surface 132 of the workpiece 130 (with or without the manufacturing tool 451), and the sensing component 430 may include the magnet 110 and field-directing polepiece 112 of the sensing system 100 (FIG. 1), or the magnet 210 and field-directing polepiece 212 of the sensing system 200 (FIG. 2), or the electromagnet 360 and the field-directing polepiece 312 of the sensing system 300 (FIG. 3), or alternate embodiments thereof. Thus, the manufacturing assembly 400 may be used to index the first location 136 on the first surface 132 of the workpiece 130 and to position a shaped magnetic field portion which may be sensed by a magnetic field sensor from an opposing side of the workpiece 130, as generally described above.

In alternate embodiments, however, the manufacturing assembly 400 may be mounted on the second surface 134, and the sensing component 430 may include a magnetic field sensor (e.g. the sensor 120). Thus, in such alternate embodiments, the manufacturing assembly 400 may be employed to move the magnetic field sensor 120 along a traversing path to detect the shaped magnetic field portion extending through the workpiece 130. The signals from the magnetic field sensor 120 may be transmitted to the controller 434, which may determine the second location 140 on the second surface 134, and may further transmit appropriate control signals to the first and second motors 440, 480, and to the manufacturing tool 451 to perform a desired manufacturing operation at the second location 140.

It should also be understood that the various operations of the manufacturing assembly 400 may be controlled by the controller 430, and may be accomplished in an automated or semi-automated manner using computerized numerically-controlled (CNC) methods and algorithms. Alternately, the various operations of the manufacturing assembly 400 may be performed manually or partially-manually by an operator, such as, for example, by having the operator provide manual control inputs to the controller 434, or by temporarily disabling or neutralizing the above-referenced motors and drive assemblies to permit manual movement. In a particular aspect, the controller 434 includes a CNC control system. It may also be noted that manufacturing assemblies in accordance with the present invention, including the manufacturing assembly 400 described above, may be operated in combination with a wide variety of manufacturing tools 451, including but not limited to, drilling devices, riveters, mechanical and electromagnetic dent pullers, welders, wrenches, clamps, sanders, nailers, screw guns, or virtually any other desired type of manufacturing tools or measuring instruments.

FIG. 5 is a flowchart of a method 500 of performing a manufacturing operation including through-skin magnetic sensing in accordance with a further embodiment of the invention. In this embodiment, the method 500 begins at a block 502, and a magnet is positioned at a desired indexing location relative to a first side of a workpiece at a block 504. As described above, the magnet may be manually positioned, or alternately, may be positioned using an automated or semi-automated manufacturing assembly, or by any other suitable means. At a block 506, a shaped magnetic field portion is generated which at least partially extends outwardly from a second side of the workpiece. The shaped magnetic field portion may be generated using one or more permanent magnets or electromagnets, in combination with one or more field-directing polepieces located on at least one of the first and second sides of the workpiece.

As further shown in FIG. 5, a magnetic field sensor may then be translated through at least a portion of the shaped magnetic field portion, and signals indicating a magnetic field strength may be sensed, at a block 508. Again, as noted above, the magnetic field sensor may be translated using an automated or semi-automated manufacturing assembly, or manually. Furthermore, the traversing path of the magnetic field sensor may be constrained, such as by maintaining a constant distance to a surface of the workpiece, or alternately, may be traversed without regard to the normality or angular orientation of the traversing path with respect to the workpiece. Then, at a block 510, a desired location for performing a manufacturing operation may be determined. This determination may include transmitting the sensed signals and analyzing the sensed signals using a controller or other suitable data analyzer.

As a block 512, the manufacturing operation may be performed at the desired location. The manufacturing operation may, for example, be drilling, welding, riveting, or any other desired operation. Then, at a block 514, a determination regarding whether the manufacturing operations are complete is made. If so, the method 500 proceeds to termination at a block 516. Alternately, the method 500 may return to the block 504, and the actions in blocks 504 through 514 may be iteratively repeated as needed until all desired manufacturing operations are accomplished.

While specific embodiments of the invention have been illustrated and described herein, as noted above, many changes can be made without departing from the spirit and scope of the invention. Accordingly, the scope of the invention should not be limited by the disclosure of the specific embodiments set forth above. Instead, the invention should be determined entirely by reference to the claims that follow.

What is claimed is:

1. A sensing system configured to locate a desired position for a manufacturing operation on a workpiece, comprising:
a first portion including a magnet having a magnetic field emanating therefrom and at least one field-directing member configured to provide a zone of approximately spherically-shaped magnetic force gradient lines, the zone having an angular extent of at least approximately three degrees and the zone at least partially extending through the workpiece and outwardly beyond a second surface of the workpiece; and
a second portion including a magnetic field sensor moveable through at least a portion of the zone extending outwardly beyond the second surface, the magnetic field sensor being configured to sense a characteristic of the zone indicative of the desired position for the manufacturing operation.

2. The sensing system of claim 1, wherein the angular extent of the zone is at least approximately five degrees.

3. The sensing system of claim 1, wherein the angular extent of the zone is at least approximately ten degrees.

4. The sensing system of claim 1, wherein the first portion is configured to provide the zone of approximately spherically-shaped magnetic force gradient lines configured such that a center of the zone may be located to within a tolerance of at least approximately 0.0001 inches.

5. The sensing system of claim 1, wherein the first portion is configured to provide the zone of approximately spherically-shaped magnetic force gradient lines configured such that a center of the zone may be located to within a tolerance of at least approximately 0.001 inches.

6. The sensing system of claim 1, wherein the at least one field-directing member includes an axisymmetrically-shaped field-directing portion.

7. The sensing system of claim 1, wherein the at least one field-directing member includes a frustrum-shaped field-directing portion.

8. The sensing system of claim 1, wherein the at least one field-directing member includes an outer portion having a first magnetic permeability and an inner portion having a second magnetic permeability.

9. The sensing system of claim 8, wherein the inner portion includes a hollow cavity.

10. The sensing system of claim 8, wherein the outer portion includes a first material and the inner portion includes a second material.

11. The sensing system of claim 1, wherein the magnetic field sensor is configured to transmit one or more signals based on the sensed characteristics of the shaped magnetic field portion, and wherein the second portion includes a data analyzer, the magnetic field sensor being configured to transmit the one or more signals to the data analyzer.

12. The sensing system of claim 1, wherein at least one of the first and second portions includes a position control assembly operatively coupled to at least one of the magnetic field sensor and the workpiece.

13. A method of performing a manufacturing operation on a workpiece, the method comprising:
providing a magnetic field;
shaping at least a portion of the magnetic field to provide a zone of approximately spherically shaped magnetic force gradient lines, the zone having an angular extent of at least approximately three degrees and the zone extending from a first side of the workpiece outwardly beyond a second side of the workpiece;
traversing a sensor through a portion of the zone extending outwardly beyond the second side of the workpiece;
sensing a characteristic of the zone; and
determining a desired location for performing the manufacturing operation on the workpiece based on the sensed characteristic.

14. The method of claim 13, wherein shaping at least a portion of the magnetic field includes shaping at least a portion of the magnetic field using a field-directing member.

15. The method of claim 13, wherein shaping at least a portion of the magnetic field includes shaping at least a portion of the magnetic field using a supplemental field-directing member from the second side of the workpiece.

16. The method of claim 13, wherein shaping at least a portion of the magnetic field includes shaping at least a portion of the magnetic field lines using an axisymmetrically-shaped portion of the field-directing member.

17. The method of claim 13, wherein shaping at least a portion of the magnetic field includes shaping at least a portion of the magnetic field using a field-directing member including a first portion having a first magnetic permeability, and a second portion having a second magnetic permeability.

18. The method of claim 13, wherein traversing a sensor includes traversing the sensor using a position control assembly.

19. The method of claim 13, wherein shaping at least a portion of the magnetic field includes shaping at least a portion of the magnetic field to provide a zone having an angular extent of at least approximately five degrees.

20. The method of claim 13, wherein shaping at least a portion of the magnetic field includes shaping at least a portion of the magnetic field to provide a zone of approximately spherically-shaped magnetic force gradient lines configured such that a center of the zone may be located to within a tolerance of at least approximately 0.0001 inches
